(19) United States
(12) Patent Application Publication
(10) Pub. No.: US 2012/0164799 A1
(43) Pub. Date: Jun. 28, 2012

(54) Method of Forming a Semiconductor Device Comprising eFuses of Increased Programming Window

(75) Inventors: Andreas Kurz, Dresden (DE); Christoph Schwan, Dresden (DE); Dirk Fimmel, Radebeul (DE)

(73) Assignee: GLOBALFOUNDRIES INC., Grand Cayman (KY)

(21) Appl. No.: 13/209,128

(22) Filed: Aug. 12, 2011

(30) Foreign Application Priority Data
Dec. 28, 2010 (DE) 10 2010 064 285.1

(51) Int. Cl. H01L 21/82

(52) U.S. Cl. 438/132; 257/E21.602

(57) ABSTRACT

In a sophisticated semiconductor device, a semiconductor-based electronic fuse may be formed in a bulk configuration, wherein the design and thus the configuration of the contact areas and the fuse region provide a wide programming window in terms of programming voltages and duration of the corresponding programming pulses.

### BACKGROUND OF THE INVENTION

1. Field of the Invention

The present disclosure generally relates to the field of fabricating integrated circuits, and, more particularly, to forming electronic fuses for providing device internal programming capabilities in complex integrated circuits.

2. Description of the Related Art

In modern integrated circuits, a very large number of individual circuit elements, such as field effect transistors in the form of CMOS, NMOS, PMOS elements and the like, are formed on a single chip area. Typically, feature sizes of these circuit elements are reduced with the introduction of every new circuit generation, to improve performance in terms of speed and/or power consumption. A reduction in size of transistors is an important aspect in steadily improving device performance of complex integrated circuits, such as CPUs. The reduction in size is commonly associated with an increased switching speed, thereby enhancing signal processing performance. In addition to the large number of transistor elements, a plurality of passive circuit elements, such as capacitors, resistors and the like, is typically formed in integrated circuits that are used for a plurality of purposes, such as for decoupling.

Due to the decreased dimensions of circuit elements, not only the performance of the individual transistor elements may be improved, but also their packing density may be increased, thereby providing the potential for incorporating more and more functions into a given chip area. For this reason, highly complex circuits have been developed, which may include different types of circuits, such as analog circuits, digital circuits and the like, thereby providing entire systems on a single chip (SoC). Furthermore, in sophisticated microcontroller devices, an increasing amount of storage capacity may be provided on chip within the CPU core, thereby also significantly enhancing the overall performance of modern computer devices.

In modern integrated circuits, minimal features sizes have now reached approximately 50 nm and less, thereby providing the possibility of incorporating various functional circuit portions at a given chip area, wherein, however, the various circuit portions may have a significantly different performance, for instance with respect to lifetime, reliability and the like. For example, the operating speed of a digital circuit portion, such as a CPU core and the like, may depend on the configuration of the individual transistor elements and also on the characteristics of the metallization system, which may include a plurality of stacked metallization layers so as to comply with a required complex circuit layout. Thus, highly sophisticated manufacturing techniques may be required in order to provide the minimum critical feature sizes of the speed critical circuit components. For example, sophisticated digital circuitry may be used on the basis of field effect transistors which represent circuit components in which the conductivity of a channel region is controlled on the basis of a gate electrode that is separated from the channel region by a thin dielectric material. Performance of the individual field effect transistors is determined by, among other things, the capability of the transistor to switch from a high impedance state into a low impedance state at high speeds, wherein also a sufficiently high current may be driven in the low impedance state. This current drive capability is determined by, among other things, the length of the conductive channel that forms in the channel region upon application of an appropriate control voltage to the gate electrode. For this reason and in view of the demand to increase the overall packing density of sophisticated semiconductor devices, the channel length and thus the length of the gate electrode is continuously being reduced which, in turn, may require an appropriate adaptation of the capacitive coupling of the gate electrode to the channel region. Consequently, the thickness of the gate dielectric material may also have to be reduced in order to maintain controllability of the conductive channel at a desired high level. However, the shrinkage of the gate dielectric thickness may be associated with an exponential increase of the leakage currents, which may directly tunnel through the thin gate dielectric material, thereby contributing to enhanced power consumption and thus waste heat, which may contribute to sophisticated conditions during operation of the semiconductor device. Moreover, charge carriers may be injected into the gate dielectric material and may also contribute to a significant degradation of transistor characteristics, such as threshold voltage of the transistors, thereby also contributing to variability of the transistor characteristics over the lifetime of the product. Consequently, reliability and performance of certain sophisticated circuit portions may be determined by material characteristics and process techniques for forming highly sophisticated circuit elements, while other circuit portions may include less critical devices which may thus provide a different behavior over the lifetime compared to critical circuit portions. Consequently, the combination of the various circuit portions in a single semiconductor device may result in a significant different behavior with respect to performance and reliability, wherein also the variations of the overall manufacturing process flow may contribute to a further discrepancy between the various circuit portions. For these reasons, in complex integrated circuits, frequently additional mechanisms may be implemented so as to allow the circuit itself to adapt performance of certain circuit portions to comply with performance of other circuit portions, for instance after completing the manufacturing process and/or during use of the semiconductor device, for instance when certain critical circuit portions may no longer comply with corresponding performance criteria, thereby requiring an adaptation of certain circuit portions, such as re-adjusting an internal voltage supply, resetting overall circuit speed and the like.

For this purpose, so-called electronic fuses or e-fuses may be provided in the semiconductor devices, which may represent electronic switches that may be activated once in order to provide a desired circuit adaptation. Hence the electronic fuses may be considered as having a high impedance state, which may typically also represent a programmed state, and may have a low impedance state, typically representing a non-programmed state of the electronic fuse. Since these electronic fuses may have a significant influence on the overall behavior of the entire integrated circuit, a reliable detection of the non-programmed and the programmed state may have to be guaranteed, which is accomplished on the basis of appropriately designed logic circuitry. Furthermore, since typically these electronic fuses may be actuated once over the lifetime of the semiconductor device under consideration, a corresponding programming activity may have to ensure that a desired programmed state of the electronic fuse is reliably generated in order to provide well-defined conditions for the further operational lifetime of the device. However, with the continuous shrinkage of critical device dimensions in sophisticated semiconductor devices, the reliability of programming corresponding electronic fuses may require tightly set margins for the corresponding voltages and thus current pulses used to program the electronic fuses, which may not be compatible with the overall specifications of the semiconductor devices or may at least have a severe influence on the flexibility of operating the device.

With reference to FIGS. 1a-1b, a typical electronic fuse in a sophisticated semiconductor device will now be described in order to more clearly set forth the difficulties in providing electronic fuses in advanced semiconductor devices.

FIG. 1a schematically illustrates a top view of a portion of a semiconductor device 150 which may represent any semiconductor device including sophisticated digital circuitry, such as a CPU core, a controller for graphic applications, memory areas and the like. The semiconductor device 150 may thus comprise a circuit portion 160, which may represent a sophisticated transistor element, such as a field effect transistor having a gate length of 50 nm and less, as previously discussed. Furthermore, the device 150 comprises an electronic fuse 100 that may represent a one-time programmable electronic switch, which may be converted from a low impedance state into a high impedance state upon a current pulse generated by applying an appropriate programming voltage to the electronic fuse 100. As illustrated, the fuse 100 comprises a first contact area 101 and a second contact area 102 and an intermediate region 103, provided in the form of a conductive line, which represents the actual fuse element which may alter its impedance state upon connecting the contact areas 101 and 102 with an appropriate voltage source. Typically, the contact areas 101, 102 and the conductive line 103 are formed of an appropriate electrode material, which may also be used for forming corresponding gate electrode structures of field effect transistors, such as is provided in the portion 160. For example, polysilicon in combination with a metal silicide are frequently used materials for forming the electronic fuse 100. Moreover, as illustrated, each of the contact areas 101, 102 may be connected to corresponding contact elements 121 that are formed in a contact level of the device 150, as will be described in more detail with reference to FIG. 1b.

FIG. 1b schematically illustrates a cross-sectional view of the device 150 along the line Ia of FIG. 1a. As illustrated, the device 150 comprises a substrate 151, such as a silicon substrate and the like, above which is formed a layer 152, which may represent a semiconductor layer or an insulating material, depending on the position of the electronic fuse 100 within the semiconductor device 150. Furthermore, the material 152 represents a semiconductor region, and an insulating material 153 may be provided, for instance on the basis of a material as may also be used as a gate dielectric material for forming field effect transistors. Moreover, a contact level 120 is formed above the layer 152 so as to enclose the electronic fuse 100 and other circuit elements, such as transistors and the like. Typically, the contact level comprises a dielectric material 122 in combination with an etch stop material 123, such as silicon dioxide and silicon nitride, respectively, in which are formed the contact elements 121 that usually comprise a conductive material, such as tungsten, possibly in combination with a conductive barrier material (not shown), such as titanium nitride and the like.

The semiconductor device 150 may be formed on the basis of well-established process techniques in which sophisticated circuit elements, such as gate electrodes of field effect transistors and the like, may be formed on the basis of critical dimensions of 50 nm and less. For this purpose, an appropriate gate electrode material in combination with a gate dielectric material may be provided and may be patterned on the basis of sophisticated lithography and etch techniques, wherein also the contact areas 101, 102 and the region 103 may be patterned. For example, the conductive line 103 may have a similar geometric configuration compared to gate electrode structures. That is, a width 103W (FIG. 1a) may correspond to the gate length of critical transistor elements, while a length 103L may be several hundred nanometers, depending on the overall configuration. It should be appreciated that, similarly as is the case for transistor elements, also the electronic fuse 100 is to be designed in view of not unduly consuming valuable die area in the device 150. Furthermore, in view of reliable programmability of the fuse 100, that is, of the region 103, it is preferable to provide a minimum cross-sectional area so as to allow a significant modification of the electrical behavior of the region 103 upon applying a sufficiently high current pulse flowing through the region 103. Consequently, the region 103 may be designed in accordance with the corresponding design rules for the device under consideration.

In a further advanced manufacturing stage, that is, patterning the gate electrode structures and thus the contact areas 101, 102 and the region 103, and after forming appropriate drain and source areas for transistor elements, typically the conductivity of semiconductor regions may be increased, for instance by forming a metal silicide in corresponding drain and source areas and gate electrodes, thereby also forming a metal silicide 104 in the contact areas 101, 102 and the region 103. This may be accomplished on the basis of well-established process techniques. It should be appreciated that, during the corresponding manufacturing process, respective sidewall spacers 105 may have been formed, which may typically be used for defining corresponding dopant profiles in transistor areas and act as a mask during the silicidation process. Thereafter, the contact level 120 may be formed on the basis of well-established process techniques including the deposition of the materials 123 and 122 and patterning the same in order to obtain appropriate contact openings, which are subsequently filled with conductive material, such as tungsten and the like. Next, a plurality of metallization layers (not shown) are formed, which may provide the wiring fabric for the circuit elements and also for the electronic fuse 100 in accordance with the overall circuit layout.

When operating the device 150 and programming the electronic fuse 100, a sufficiently high voltage is to be applied between the contact areas 101 and 102 in order to generate a sufficient high current density for a certain time interval, which may result in a permanent modification in order to blow the fuse 100. For example, in this case, the per se negative effect of electromigration may be efficiently used so as to induce a current driven material diffusion in the line 103, which may result in a significant modification of the electrical performance, i.e., a corresponding high impedance state may be achieved due to the degradation of the line 103. Electromigration is a well-known effect which may occur in conductive lines, typically metal-containing lines, when current density is very high so that the flow of electrons may cause a directed diffusion of the ion cores, thereby increasingly transporting material along the electron flow direction. Thus, the corresponding line may increasingly suffer from a depletion of material in the vicinity of the cathode, while material may be deposited at or next to the line in the vicinity of the anode of the fuse 100. As previously discussed, a reliable distinction between a non-programmed state and a programmed state may require a corresponding significant modification of the line 103, which may require current pulses of sufficient length supplied via appropriately designed contact areas 101, 102 and contact elements 121 connecting thereto in order to provide the required current drive capability for effecting a “blowing” of line 103. Thus, an appropriate tightly set “programming time window” for a given voltage may be required for sophisticated devices in order to obtain a high difference between the low impedance state and the high impedance state. Moreover, the corresponding margins for the programming voltage and current pulses may have also to take account any process-related fluctuations during the formation of the fuse 100, thereby requiring more tightly set programming voltages. As previously discussed, a corresponding required degree of reliability in detecting the programmable state may require sufficiently high programming voltages and/or sufficiently long current pulses.

Since typically sophisticated semiconductor devices and corresponding basic designs may be used for very different applications, for instance different supply voltages may frequently be used in combination with a different timing behavior of various circuit portions and the like, the tightly set programming windows, for instance in terms of programming voltage and programming time, frequently significant redesigns of the configuration of the electronic fuses may be required. In this case, respective new lithography masks may have to be provided for the complex gate patterning process since, in bulk configurations, the semiconductor-based electronic fuses are basically patterned together with the complex gate electrode structures. Moreover, as discussed above, frequently an adaptation of important device parameters, such as supply voltage and the like, may have to be adapted over the lifetime of the device, thereby also requiring certain programming events, which may have to be performed on the basis of a modified process parameter, such as the supply voltage, which in turn may therefore significantly affect the programming process when tightly set programming windows are initially implemented in the semiconductor device.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides manufacturing techniques and programming techniques in which electronic fuses may be formed on the basis of a semiconductor material, such as silicon in amorphous or polycrystalline state, silicon/germanium, germanium and the like, wherein the electronic fuses are fabricated with sophisticated gate electrode structures, while nevertheless providing an increased programming window, for instance with respect to the required programming voltage and the length of the corresponding current pulses applied. In this manner, very efficient electronic fuses may be provided for bulk configuration, i.e., for semiconductor devices in which the active semiconductor material is in direct contact with a crystalline material of the substrate, which usually results in a very efficient heat dissipation, which is, however, not desirable in view of enhancing the programming efficiency in electronic fuses. Consequently, the electronic fuses may be formed on appropriate isolation regions, such as trench isolations formed in the active semiconductor material, thereby significantly reducing the heat dissipation capability due to the significantly lower heat conductivity of the dielectric material compared to a semiconductor material. On the other hand, the design criteria and thus the finally obtained configuration of the electronic fuses are selected such that the detectable irreversible modifications in the electronic fuses may be induced for a wide range of operating voltages and/or programming pulses. To this end, a robust configuration of corresponding fuse heads or contact areas are provided which allow a low resistance connection to any contact elements, while on the other hand a high degree of current crowding may be obtained at the transition from the contact area or fuse head into the actual fuse region, in which a pronounced current density is to be established in order to obtain the desired permanent modification of the electronic behavior in the fuse region. Consequently, based on design-specific concepts, such as specifically designed fuse heads or contact areas, possibly in combination with specifically configured contact elements in combination with an appropriate transition and overall configuration of the actual fuse region, a reliable programming effect may be obtained for a wide range of programming voltages and programming time intervals.

One illustrative method disclosed herein relates to forming an electronic fuse of an integrated circuit. The method comprises forming an electrode material above an insulating material that is formed above a substrate of the integrated circuit. Moreover, the method comprises forming a first contact area, a second contact area and a fuse region of the electronic fuse from the electrode material, wherein the fuse region connects to the first and second contact areas. Moreover, the method comprises forming contact elements in the contact level of the integrated circuit. The contact elements connect to the first and second contact areas of the electronic fuse and have a length dimension and a width dimension, wherein the length dimension differs from the width dimension.

A further illustrative method disclosed herein relates to forming an electronic fuse of a semiconductor device. The method comprises forming a first contact area and a second contact area of the electronic fuse from a semiconductor material that is formed above an isolation region. Moreover, the first and/or the second contact region have a length that is greater than a width thereof. The method further comprises forming a fuse region from the semiconductor material laterally between and in contact with the first and second contact regions. Furthermore, a plurality of contact elements is formed so as to connect to the first and second contact areas.

A further illustrative method disclosed here comprises forming a plurality of circuit elements in and above a semiconductor layer. Moreover, an electronic fuse is formed on an isolation region so as to comprise a first contact area, a second contact area and a fuse region. The method further comprises forming a contact level above the semiconductor layer, wherein the contact level comprises a first plurality of contact elements connecting to the first contact area and a second plurality of contact elements connecting to the second contact area and wherein each contact element of the first and second pluralities has a rectangular shape according to a top view. Furthermore, the method comprises forming a metallization system above the contact level and applying a programming voltage to the electronic fuse that is equal to or less than 1.7 volts.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a conventional semiconductor device including an electronic fuse;

FIG. 1b schematically illustrates a cross-sectional view of the electronic fuse of the conventional device as shown in FIG. 1a;

FIG. 2a schematically illustrates a top view of a semiconductor device comprising an electronic fuse having a superior configuration in order to obtain superior programming characteristics, according to illustrative embodiments;

FIG. 2b schematically illustrates a cross-sectional view of the semiconductor device in which a circuit element, such as a sophisticated gate electrode structure, and a fuse region are illustrated, which may be formed in a common manufacturing process, according to illustrative embodiments; and

FIG. 2c schematically illustrates a cross-sectional view of the semiconductor device in which a fuse region and a gate electrode structure may be provided on the basis of superior design criteria and on the basis of sophisticated material systems, such as a high-k dielectric material and a metal-containing electrode material, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

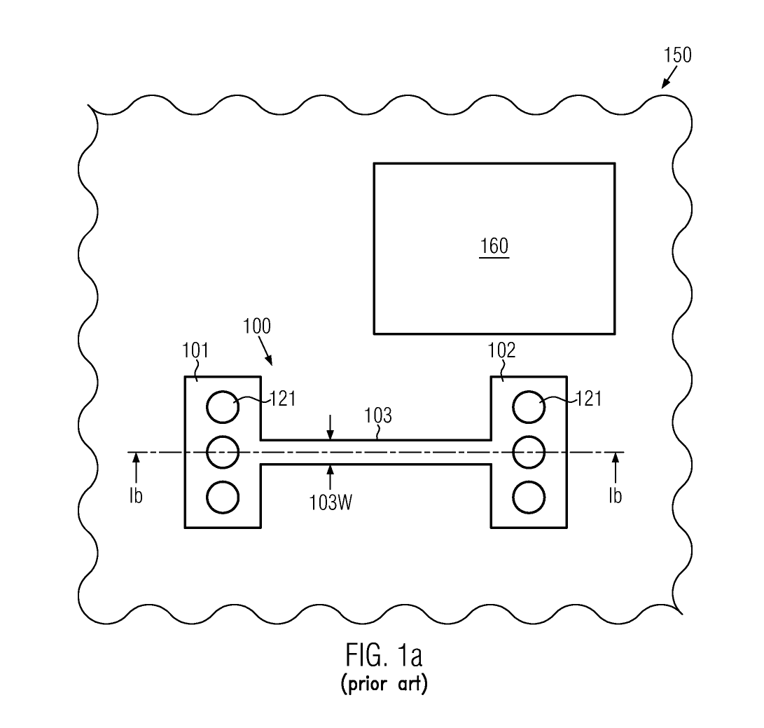

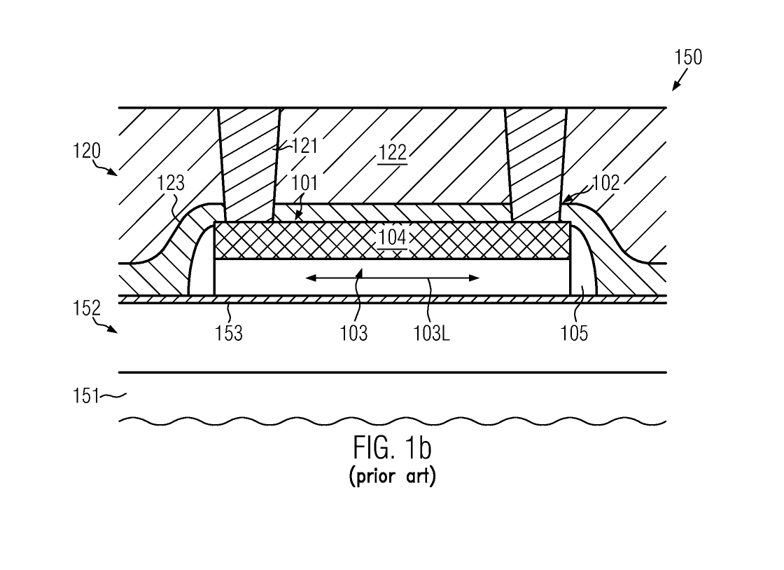

Basically, the present disclosure contemplates semiconductor-based electronic fuses which may be formed together with sophisticated gate electrode structures, thereby implementing an efficient programming mechanism into sophisticated semiconductor devices, which, for instance, may be formed on the basis of a bulk configuration, since in this case it is difficult to provide semiconductor-based electronic fuses without having to provide additional mechanisms in order to address the problem of superior heat conductivity of a bulk semiconductor material. Thus, in some illustrative embodiments disclosed herein, the methods for forming the semiconductor-based electronic fuses use an isolation structure, such as a shallow trench isolation and the like, thereby reducing the thermal coupling of the actual fuse region of the electronic fuse with respect to the substrate material, which may generally allow reducing the programming voltages and/or the duration of the programming pulses, while at the same time providing the electronic fuses with reduced overall lateral dimensions. To this end, certain design criteria may be realized upon forming the electronic fuse, wherein, in some illustrative embodiments, a superior configuration of the contact areas or fuse heads in combination with the contact elements may be implemented in order to provide a high current drive capability, thereby reducing the power losses in the fuse heads while at the same time providing a required high current density at the actual fuse region, in which the high current density is to induce a permanent damage and thus create a reliably detectable modification of the electronic behavior. For example, in some illustrative embodiments, the contact elements are provided in a rectangular configuration when considered in top view, thereby enabling an increase of the overall cross-sectional area for a given desired design or configuration of the contact heads. For example, superior contact resistance may be accomplished compared to conventional square-like contact elements or substantially roundish contact elements, as, for instance, described above with reference to FIGS. 1a and 1b. In this manner, the contact elements may be efficiently implemented into the contact heads, which in some illustrative embodiments may also have a substantially rectangular configuration with respect to a top view, wherein, in some cases, a length of the contact areas may be greater than a width thereof.

In this respect, generally a length direction is to be considered a lateral direction in a semiconductor device, which corresponds basically to a current flow direction. A width direction generally indicates a lateral direction that is perpendicular to the length direction. Furthermore, generally a depth or “vertical” direction is to be understood as a direction that is substantially perpendicular to the length and width directions.

For example, in some illustrative embodiments disclosed herein, a fuse region, which may be laterally positioned between the contact areas of the electronic fuse, may have a length that is less than a length of at least one of the contact areas. In this manner, in total, a very laterally compact configuration of the electronic fuse may be obtained, while at the same time pronounced variability of programming conditions is acceptable, thereby enabling the usage of the basic fuse configuration for a variety of sophisticated applications. Moreover, due to these design criteria, a certain adaptation of the fuse characteristics, such as the programming behavior, may be accomplished by appropriately adapting the lateral dimensions of the fuse region, for instance length and/or width, which may be accomplished without any significant redesigns, thereby providing the potential for a further increase of the programming window compared to conventional strategies. For example, the length of the fuse region may be readily adapted for otherwise non-changed overall dimensions, since the fuse heads may be appropriately reduced in length, however, without actually significantly modifying the electronic behavior thereof. Moreover, based on the overall rectangular configuration of the contact areas, wherein typically a length thereof may be greater than a width, a desired abrupt transition to the actual fuse region may be obtained, thereby contributing to increased current crowding and thus electromigration efficiency in this area.

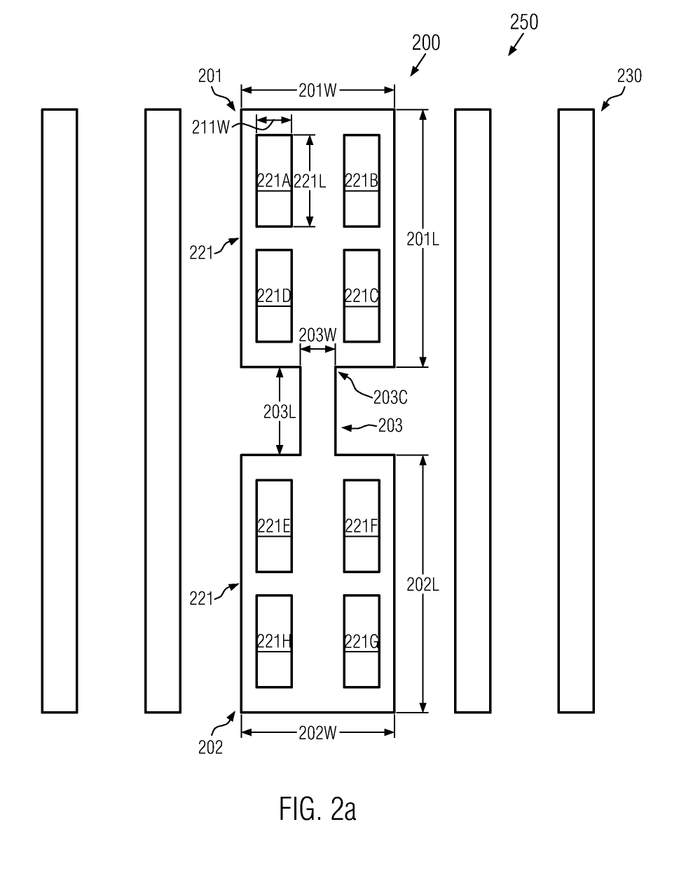

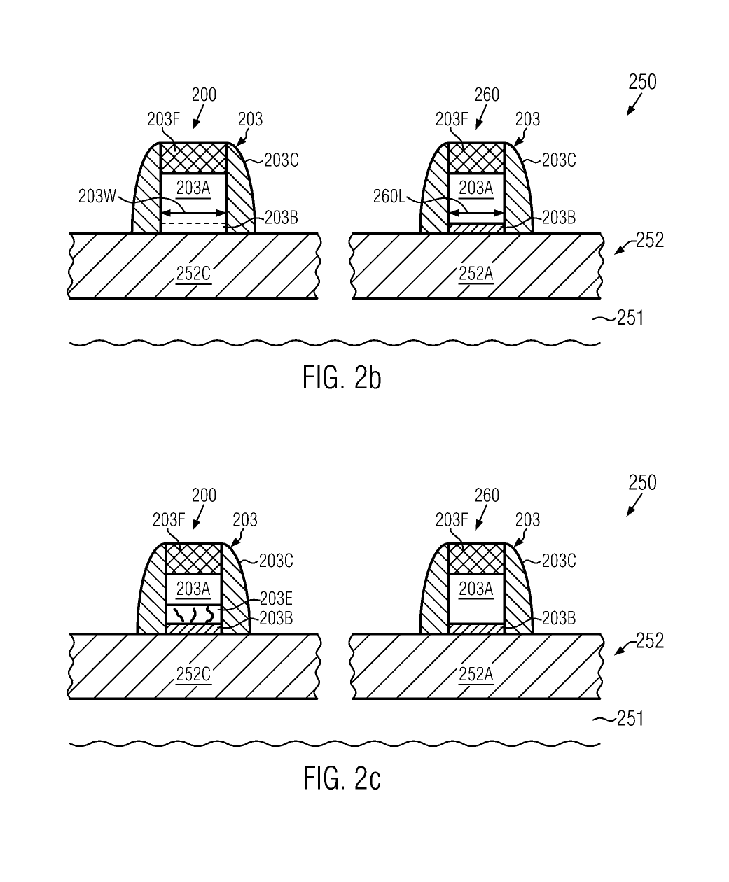

With reference to FIGS. 2a-2c, further illustrative embodiments will now be described in more detail, wherein reference may also be made to FIGS. 1a-1b, if appropriate.

FIG. 2a schematically illustrates a top view of a semiconductor device 250, which may comprise an electronic fuse 200 of superior programming characteristics. The electronic fuse 200 may be provided in any appropriate device area of the device 250, possibly in combination with additional structures 230, such as semiconductor-based line structures, which may be provided with respect to finding an appropriate neighborhood of the electronic fuse 200, while in other cases the structures 230 may also provide certain electronic characteristics, as required by the overall design of the device 250. It should be appreciated that, in other device areas, any other circuit elements may be provided, such as sophisticated gate electrode structures, as will be described later on in more detail with reference to FIGS. 2b and 2c. As illustrated, the electronic fuse 200 may comprise a first contact area or fuse head 201 and a second contact area or fuse head 202, while a fuse region 203 is laterally positioned between the first and second contact areas 201, 202. As discussed above, in some illustrative embodiments, as will also be described in more detail later on, the electronic fuse 200 and thus the components 201, 202 and 203 may be formed on an isolation region, which may provide reduced thermal conductivity with respect to the remaining portion of a substrate of the device 250. The contact areas 201, 202 may actually provide a low resistance contact area for connecting to other circuit elements, such as transistors, which may have to provide the required current pulses for inducing a reliably detectable modification within the fuse region 203. To this end, the contact areas 201, 202 are basically designed so as to provide superior current drive capability in combination with corresponding contact elements 221, while at the same time a geometrically very abrupt transition, that is, moderately sharp corners, may be provided with respect to the fuse region 203. For example, as indicated by the corners 203C, the design of the electronic fuse 200 may exhibit a pronounced angle, for instance a ninety degree angle, which may, as is well known, result in a more or less pronounced sharp corner in the actual implementation when pattering the electronic fuse 200 on the basis of a specific lithography mask implementing the desired design of the corner 203C. In the embodiment shown, the contact area has a length 201L and a width 201W, thereby defining, according to the top view as shown in FIG. 2a, a substantially rectangular shape wherein the length 201L is greater than the width 201W. Consequently, in this manner, the contact area 201 has a somewhat elongated shape with respect to a general length direction of the fuse 200, which is basically defined by the current flow direction within the fuse region 203. That is, it should be appreciated that basically the length direction may be defined with respect to the current flow direction of the fuse region 203, while in other areas, such as the contact elements 221 and the contact areas 201, 202, current flow may also occur in other directions, in particular at the critical corner areas 203C. Similarly, in the contact elements 221, the general current flow direction may occur substantially perpendicularly to the drawing plane of FIG. 2a, while nevertheless a length 221L and a width 221W may be defined in compliance with the corresponding definition of length and width of the fuse region 203 and the contact areas 201, 202. In other words, the length 203L of the fuse region 203 defines a lateral direction which may commonly be referred to as length direction for any component of the electronic fuse 200. Similarly, a width 203W of the fuse region may generally define a lateral direction, perpendicular to the length direction, which may also commonly be used as a width direction for any component of the electronic fuse 200. In this sense, any of the contact elements, although substantially extending from the drawing plane of FIG. 2a, may have the length 221L, at least in the area connecting to the contact areas 201, 202, respectively, and may also have the width 221W, which in some illustrative embodiments are selected such that a rectangular shape is obtained, wherein the length 221L is greater than the width 221W.

The contact area 201 may comprise a plurality of the contact elements 221, such as contact elements 221A, 221B, 221C, 221D, each of which may thus be appropriately adapted to the elongated shape of the contact area 201, thereby providing an increased overall contact area for reducing the overall contact resistivity of the contact area 201. Similarly, the contact area 202 may comprise a plurality of contact elements 221E, 221F, 221G, 221H, each of which may also have a substantially rectangular and thus elongated shape, wherein, in some illustrative embodiments, the plurality of contact elements 221A, 221B, 221C, 221D may have the same configuration and may also have the same configuration as the plurality of contact elements 221E, 221F, 221G, 221H in the contact area 202. In other illustrative embodiments (not shown), the contact elements in the contact elements 201, 202 may individually differ from each other or at least the lateral dimensions of each contact element in one plurality of contact elements, for instance in the contact area 202, may differ from the lateral dimensions of the contact elements provided in the other contact area 201. In this manner, the current drive capability of the contact areas and thus also of the contact elements may be adapted to the expected current densities required for effecting the programming of the fuse 200, wherein these current drive capabilities may be selected differently for the cathode and anode of the electronic fuse 200.

The lateral dimensions of the fuse region 203 are selected such that a desired modification may be induced, for instance caused by electromigration in combination with an increased heat generation during the programming event, as discussed above, wherein, in particular at the corner areas 203C, an increased degree of current crowding may be generated. For example, the width 203W may be selected so as to be compatible with overall patterning conditions when forming gate electrode structures or any other structures, such as the structures 230, wherein, in some illustrative embodiments, comparable lateral dimensions may be used, as may be implemented in gate electrode structures of sophisticated transistors. For example, the width 203W may correspond to a length of gate electrodes that may be the same order of magnitude, which may be 50 nm or less in sophisticated applications. Similarly, the length 203L may be appropriately adapted by taking into account the overall electronic characteristics of the fuse region 203, for instance with respect to its sheet resistivity, the semiconductor materials used therein, possibly in combination with any further conductive materials, such as metal-containing electrode materials in sophisticated high-k metal gate electrode structures, metal silicide, as is typically provided so as to induce the pronounced electromigration effect and the like. In the embodiment shown, the length 203L may be selected to be approximately 100 nm and higher, depending on the required overall resistance, wherein, in illustrative embodiments, the length 203L may be less than a length of the contact areas 201 and/or 202. In this manner, generally high current drive capability of the contact areas 201, 202 with respect to the required current density within the fuse region 203 may be ensured. Moreover, if desired, a specific modification of the fuse 200 may be accomplished, for instance without requiring a change in the overall lateral dimensions by increasing the length of the fuse region 203, while at the same time reducing the length of one or both of the contact areas 201, 202. In this manner, the generally wide programming window of the fuse 200 may be readily further increased by minor design or process modifications.

The semiconductor device 250 as shown in FIG. 2a may be formed on the basis of process techniques as are, for instance, also described above with reference to the semiconductor device 150, wherein, however, appropriate lithography masks taking account of the basic design of the fuse 200 may be used in forming the fuse 200 together with other circuit elements, such as gate electrode structures, as discussed above. That is, an appropriate isolation region may be formed, for instance, by well-established shallow trench isolation techniques in order to provide a region of low thermal conductivity for forming thereon the electronic fuse 200. Thereafter, appropriate materials may be deposited or formed in any other manner, for instance by oxidation, as is required for providing sophisticated gate electrode structures. Next, the resulting material layer stack may be patterned so as to obtain the configuration of the contact areas 201, 202 and the of the fuse region 203, together with any other structures such as the line structures 230 and other gate electrode structures, wherein, as discussed above, even critical dimensions may be used in the fuse region 203 in order to implement a desired electronic behavior of the electronic fuse 200. Thereafter, the further processing may be continued so as to complete electronic circuit elements, such as transistors, and after any high temperature processes, if required, a further adjustment of the overall characteristics may be implemented, for instance by forming a metal/semiconductor compound, such as a metal silicide, in a portion of the semiconductor material used for providing the electronic fuse 200 and other gate electrode structures. Next, the contact level of the device 250 may be provided, for instance by forming two or more dielectric materials and patterning the same, thereby forming contact openings that may represent the contact elements 221 and any other contact elements formed in other device regions. It should be appreciated that, as discussed above, the contact elements 221 may be provided with a substantially longitudinal shape with respect to the top view as shown in FIG. 2a, thereby providing superior conductivity and contact resistance wherein, as shown, the width 221W may be formed on the basis of critical dimensions, as may also be used in other contact elements, such as square-like contact elements, roundish contact elements, as for instance shown in FIG. 1a, and the like. Consequently, at least in one lateral dimension, i.e., in the width direction, a very compact configuration may be obtained, while at the same time a high current drive capability is established and a high degree of current crowding is obtained in the corner areas 203C due to the overall rectangular and thus elongated configuration of the contact elements 221 and their position within the contact areas 201, 202. Moreover, the overall configuration of the contact areas 201, 202 is selected such that any process fluctuations upon forming the contact elements 221 may not negatively influence the overall electronic characteristics. That is, the design is such that any process-related misalignments and the like may not unduly affect performance of the electronic fuse 200, thereby also imparting superior programming efficiency to the device 200. Similarly, due to the superior shape of the contact elements 221, these contact elements may also be reliably connected to corresponding metal lines provided in the very first metallization layer (not shown) that is to be formed above the contact level of the device 250. Also in this case, superior process robustness may be achieved due to the overall configuration of the electronic fuse 200.

FIG. 2b schematically illustrates a cross-sectional view of the semiconductor device 250 wherein the electronic fuse 200 is formed above an isolation region 252C, which may represent a shallow trench isolation that laterally delineates a semiconductor layer 252 into a plurality of active semiconductor regions, such as a region 252A, in and above which corresponding circuit elements 260 may be formed. It should be appreciated that, in some illustrative embodiments, the semiconductor region 252A may directly connect to a crystalline semiconductor material of a substrate 251, thereby forming a bulk configuration, as is also discussed above. In this case, the isolation region 252C provided for forming the electronic fuse 200 may thus result in a significantly reduced heat dissipation capability, thereby significantly contributing to a reliable programming behavior of the fuse 200, as is also discussed above. It should be appreciated that the cross-section shown in FIG. 2b may be a cross-section through the fuse region 203 along the width direction. Consequently, the fuse region 203 may have the width 203W, as discussed above with reference to FIG. 2a, wherein the width 203W may also represent the electrically effective width, since the fuse region 203, as well as the contact areas 201, 202 (FIG. 2a) may comprise a sidewall spacer structure 203C, depending on the overall device requirements. Moreover, in the embodiment shown, a dielectric material 203B may be provided on the isolation region 252C, depending on the process strategy used for forming the electronic fuse 200 in combination with the circuit element 260, which in some illustrative embodiments represents a gate electrode structure. Moreover, the fuse 200 may comprise a semiconductor material 203A, such as amorphous silicon, polysilicon, a silicon/germanium mixture, a germanium material and the like, depending on the required sheet resistance of the electronic fuse 200, in particular in the fuse region 203. Moreover, a metal/semiconductor compound 203F, for instance in the form of a metal silicide, depending on the fraction of silicon material contained in the semiconductor material 203A, may be provided. It should be appreciated that basically the same configuration may be provided in the contact areas 201, 202, as is also described in a similar manner for the conventional device 100 when referring to FIGS. 1a and 1b. It should be noted, however, that a different configuration may be used in the contact areas 201, 202 and the fuse region 203, if considered appropriate. For example, the metal/semiconductor compound 203F may be selectively omitted in the fuse region 203 or the configuration thereof, for instance the thickness thereof, may be reduced in the fuse region 203 if a reduced overall current drive capability is desirable compared to a desired high current drive capability in the contact areas 201, 202 of FIG. 2a. In FIG. 2b, the gate electrode structure 260 is illustrated so as to have substantially the same configuration, wherein it should be appreciated that specific differences may be implemented, for instance in terms of the overall conductivity of the semiconductor material 203A, the characteristics of the metal/semiconductor compound 203F and the like. Moreover, the gate dielectric material 203B is formed on the active region 252A, even if an oxidation process may be applied for forming the material 203, while in this case the layer 203B may not be present in the electronic fuse 200. In other cases, the dielectric layer 203B may be formed by deposition, at least partially, and hence any deposited material may also be present in the electronic fuse 200.

As discussed above, the electronic fuse 200 and the gate electrode structure 260 may basically be formed in a common manufacturing strategy, wherein, however, a length 260L of the gate electrode structure 260 may be adjusted in accordance with transistor requirements, while the width 203W may be selected so as to obtain the desired modification of the state of the electronic fuse 200 upon performing a programming process. As discussed above, the width 203W may be comparable to the length 260L in sophisticated applications.

FIG. 2c schematically illustrates a cross-sectional view of the device 250 in which the gate electrode structure 260 may be provided in the form of a sophisticated high-k metal gate electrode structure, in which the gate dielectric layer 203B may comprise a high-k dielectric material. Generally, herein a high-k dielectric material may be understood as a dielectric material having a dielectric constant of 10.0 and higher. For example, a plurality of metal-based dielectric materials, such as hafnium oxide, zirconium oxide and the like, may be used as efficient high-k dielectric material. In some illustrative embodiments, the dielectric layer 203B may additionally comprise a conventional dielectric base material, for instance in the form of a silicon oxynitride material in combination with a high-k dielectric material, thereby providing superior capacitance values while nevertheless preserving a certain desired minimum thickness of the gate dielectric material 203B. Moreover, in this case, the gate electrode structure 260 may also comprise a metal-containing electrode material 203E, for instance in the form of titanium nitride and the like, possibly in combination with additional metal species, such as lanthanum, aluminum and the like, as required for defining the electronic characteristics of the structure 260, for instance in terms of work function and thus threshold voltage of a transistor and the like. Furthermore, the material 203A may be provided in the form of a semiconductor material, such as amorphous or polycrystalline silicon and the like. Similarly as discussed above, the metal/semiconductor compound 203F may be provided. In some approaches, the high-k metal gate electrode structure 260 may be formed on the basis of process techniques in which the dielectric layer 203B including the high-k dielectric material and the electrode material 203E may be provided in an early manufacturing stage, i.e., upon forming and patterning a corresponding gate layer stack. Consequently, in any such manufacturing strategy, the corresponding material 203B, possibly without an oxidation-based conventional dielectric material, and the metal-containing electrode material 203E, may also be provided in the electronic fuse 200 and may possibly affect the overall electronic behavior, since typically the material 203E may have a greater conductivity compared to even highly doped semiconductor material, such as amorphous or polycrystalline silicon material. Consequently, in some illustrative embodiments, the electronic characteristics of the material 203E may be selectively adjusted in the electronic fuse 200 in order to, for instance, reduce the conductivity thereof and the like. For example, the crystalline structure may be damaged selectively in the fuse 200, for instance selectively in the fuse region 203 in some illustrative embodiments so that the electronic behavior may be substantially determined by the materials 203A and 203F. To this end, upon forming the gate electrode structure 260 and the electronic fuse 200 at any appropriate manufacturing stage, a corresponding implantation process may be applied for damaging the material 203E selectively in the fuse 200. In other cases, material 203E may be removed selectively from the fuse 200 prior to depositing the semiconductor material 203A.

Consequently, also in this case, the electronic fuse 200 and the gate electrode structure 260 may be formed in a common manufacturing process, while the superior configuration of the electronic fuse 200 ensures a wide programming window.

For example, upon operating the electronic fuse 200, which may have lateral dimensions as specified above, programming voltages of approximately 1.2-1.7 volts may result in a programming efficiency of 100 percent for current pulses having a duration of 5-50 micro seconds. Consequently, the same manufacturing techniques of the electronic fuse 200 may be used for a wide variety of different conditions upon programming the fuse 200 in various applications, while nevertheless ensuring a reliable detection of the programmed state.

As a result, the present disclosure provides manufacturing techniques in which electronic fuses may be formed with superior configuration in order to ensure a reliable programming behavior for a wide range of programming voltages and a wide range of current pulses so that basically the same fuse configuration may be used in very different applications.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming an electronic fuse of an integrated circuit, the method comprising:
forming an electrode material above an insulating material formed above a substrate of said integrated circuit;
forming a first contact area, a second contact area and a fuse region of said electronic fuse from said electrode material, said fuse region connecting to said first and second contact areas; and
forming contact elements in a contact level of said integrated circuit, said contact elements connecting to said first and second contact areas of said electronic fuse and having a length dimension and a width dimension, said length dimension differing from said width dimension.

2. The method of claim 1, wherein said length dimension and said width dimension define a rectangular-shaped area in said first and second contact areas.

3. The method of claim 1, wherein a width of said fuse region is approximately 50 nm or less.

4. The method of claim 1, wherein forming said first and second contact areas and said fuse regions comprises forming a metal silicide in said electrode material.

5. The method of claim 1, wherein forming said first and second contact areas and said fuse region comprises providing said electrode material at least partially as a metal-containing material prior to patterning said electrode material.

6. The method of claim 1, wherein said first and second contact areas are formed so as to each have a contact length that is greater than said length dimension.

7. The method of claim 1, wherein said first and second contact areas are formed so as to have a contact width that is less than a contact length.

8. The method of claim 1, wherein forming an electrode material above an insulating material comprises forming a trench isolation region in a semiconductor layer and forming said electrode material above said trench isolation region.

9. The method of claim 8, wherein forming said electrode material comprises depositing a polycrystalline semiconductor material.

10. A method of forming an electronic fuse of a semiconductor device, the method comprising:
forming a first contact area and a second contact area of said electronic fuse from a semiconductor material formed above an isolation region, at least one of said first and second contact regions having a length that is greater than a width;
forming a fuse region from said semiconductor material laterally between and in contact with said first and second contact regions; and
forming a plurality of contact elements so as to connect to said first and second contact areas.

11. The method of claim 10, further comprising determining a programming voltage and adjusting a length of said fuse region on the basis of said determined programming voltage.

12. The method of claim 11, wherein said length of said fuse region is less than a length of at least one of said first and second contact areas.

13. The method of claim 10, wherein each of said plurality of contact elements is formed as a rectangular contact element.

14. The method of claim 10, wherein forming said fuse region comprises providing a metal-containing material on a dielectric layer and forming said semiconductor material above said metal-containing material.

15. The method of claim 10, wherein forming said fuse region comprises selecting a target width of 50 nm or less and patterning said semiconductor material of said fuse region by using said target width.

16. A method, comprising:
forming a plurality of circuit elements formed in and above a semiconductor layer;
forming an electronic fuse on an isolation region so as to comprise a first contact area, a second contact area and a fuse region;
forming a contact level above said semiconductor layer, said contact level comprising a first plurality of contact elements connecting to said first contact area and a second plurality of contact elements connecting to said second contact area, each contact element of said first and second pluralities having a rectangular shape according to a top view;
forming a metallization system above said contact level; and
applying a programming voltage to said electronic fuse that is equal to 1.7 volts or less.

17. The method of claim 16, wherein said programming voltage is in the range of 1.2-1.7 volts.

18. The method of claim 17, wherein said programming voltage is applied for a time interval of 5-50 microseconds.

19. The method of claim 16, wherein forming said electronic fuse comprises forming said first and second contact areas so as to have a rectangular shape with respect to a top view and selecting a lateral extension in a length direction to be greater than a lateral extension in a width direction.

20. The method of claim 16, wherein forming said fuse region comprises forming a conductive metal-containing material below said semiconductor material.
